(19) United States
(12) Patent Application Publication
(10) Pub. No.: US 2026/0336159 A1
(43) Pub. Date: Oct. 29, 2026

(54) LASER OBJECT PRINTING FROM A GASEOUS SUBSTRATE

(71) Applicant: Orca Sciences LLC, Kirkland, WA (US)

(72) Inventors: Patrick Gallagher, Kirkland, WA (US); Ian Salmon McKay, Kirkland, WA (US); Menyoung Lee, Kirkland, WA (US)

(73) Assignee: Orca Sciences LLC, Kirkland, WA (US)

(21) Appl. No.: 19/114,199

(22) PCT Filed: Oct. 2, 2023
(86) PCT No.: PCT/US2023/034308

§ 371 Date: Mar. 21, 2025

(51) Int. Cl. B28B 1/00; B33Y 10/00; B33Y 30/00; B33Y 50/02; B33Y 80/00; D01F 9/08; D01F 9/12

(52) U.S. Cl. CPC B28B 1/001; B33Y 10/00; B33Y 30/00; B33Y 50/02; B33Y 80/00; D01F 9/08; D01F 9/12; D10B 2101/16

(57) ABSTRACT

Methods and apparatus to 3D print solid materials from the gas phase, as well as recover valuable gaseous coproducts. In some reactor designs, a novel configuration of efficient, low-cost, semiconductor lasers is used.

### CROSS-REFERENCE TO RELATED APPLICATIONS

The present application claims the benefit of and priority to U.S. provisional application No. 63/378,357, filed on Oct. 4, 2022, and U.S. provisional application No. 63/432,139, filed on Dec. 13, 2022, the entire disclosure of each of which is hereby incorporated by reference as if set forth in its entirety herein.

### TECHNICAL FIELD

Embodiments described herein generally relate to methods and systems for fabricating solid objects from a gaseous feedstock, and more specifically to a printer using laser radiation to cause solidification of the feedstock in specific locations to form a desired object.

### BACKGROUND

A small field of literature originating in the 1980s demonstrated laser-based growth of carbon fiber from low-cost, gaseous hydrocarbon feedstocks (e.g., methane or olefins). The laser may be focused to sustain a few-micron-diameter hot spot (e.g., hundreds to thousands of degrees Celsius) on a suitable surface; feedstock gas locally pyrolyzes and deposits solid carbon, thereby growing a narrow fiber if the focus is continually adjusted to remain near the tip of the deposit. The diameter of the grown fiber is typically well matched to the focused optical spot size.

Under appropriate growth conditions, the tensile strength and tensile modulus of the resulting fibers may compete with carbon fibers produced via polyacrylonitrile. The needed optical energy per mass of deposited carbon fiber may be well below 100 MJ/kg, which suggests the possibility of significant energetic improvements on the polyacrylonitrile process. Literature reports include linear fiber growth rates typically in the regime of 10 micron to 1 mm per second. Very similar techniques may also be used to grow other fibers from gaseous precursors (e.g., boron fibers from BCl₃ and H₂, silicon carbide fibers from SiCl₄ and CH₄, silicon fibers from SiCl₄ and H₂, tungsten fibers from WF₆ and H₂, germanium fibers from GeH₄ and H₂, etc.), often at similar growth rates and with similar energy requirements.

A major problem in commercializing this technology has been the energetic efficiency of the lasers. As an example, if the optical energy intensity required to grow a specific fiber is 100 MJ/kg (a common order of magnitude found in the literature), but the laser system used is only 10% efficient in converting electrons from the power outlet into photons striking the target (this 10% figure is typical of the sorts of lasers used in the literature, e.g., Nd:YAG or fiber lasers), the electricity required for fiber growth would be 1000 MJ/kg. Using a typical industrial electricity cost of $0.08/kWh, the electricity alone would amount to over $22/kg, which would make any fiber grown by this method rather expensive.

The capital cost of the growth equipment has presented yet another commercial roadblock. Lasers with high-quality optical modes (e.g., fiber lasers) have been used for controlled fiber growth, but often cost in excess of $20/W; amortizing such an expense over a laser lifetime of 10 years at 100% utilization, the laser capital cost would effectively contribute $ 0.22/kWh, or 2.5 times the cost of electricity, which already contributed $ 22/kg in our example above.

Accordingly, there is a need for laser-fabricating systems and methods that overcome these disadvantages.

### SUMMARY

This summary is provided to introduce a selection of concepts in a simplified form that are further described below in the Detailed Description section. This summary is not intended to identify or exclude key features or essential features of the claimed subject matter, nor is it intended to be used as an aid in determining the scope of the claimed subject matter.

Embodiments of the present invention relate to a method and apparatus to 3D print solid materials from the gas phase, as well as recover valuable gaseous coproducts, by harnessing a similar physical mechanism to that described above for fibers. In some reactor designs, a novel configuration of efficient, low-cost, semiconductor lasers is used to overcome the aforementioned commercialization challenges associated with laser-induced deposition from the gas phase.

In one aspect, embodiments relate to a laser reactor for additive manufacturing. The reactor includes a reaction chamber having an intake for receiving a gaseous feedstock, an optical window, and a substrate; and a laser module, wherein the laser module is configured to emit laser light to heat the substrate through the window and thereby drive a gas-to-solid deposition reaction in the vicinity of the heated substrate converting the gaseous feedstock into at least one reaction product which forms at least part of a desired solid object supported by the substrate.

In various embodiments the substrate has at least one degree of freedom.

In various embodiments the at least one reaction product is a refractory material.

In various embodiments the laser module is mobile and has at least one degree of freedom.

In various embodiments the laser module comprises a plurality of laser emitters and the reactor further comprises an optical mechanism configured to cause the output of each of the laser emitters to strike different areas of the substrate.

In various embodiments the reactor further includes a first optical element to split the output of the laser module into multiple beams and a second optical element configured to cause each beam to strike a different area of the substrate.

In various embodiments the reactor further includes a plurality of optical windows and a plurality of laser modules, wherein each laser module of the plurality of laser modules is configured to emit laser light into the chamber through an optical window of the plurality of optical windows and the laser light of the plurality of laser modules converges on an area of the substrate.

In various embodiments the reactor further includes a mechanism for adjusting one or more of the pressure of the reactor, the temperature of the substrate, and the temperature of the reactants.

In various embodiments the reactor further includes an optical element for controlling the target of the emitted laser light in the reaction chamber.

In various embodiments the reactor further includes a controller in communication with at least one sensor, the controller configured to control at least one of the power, the deflection, or the position of the laser module based on information received from the at least one sensor.

In various embodiments the desired object is an array of carbon fibers.

In various embodiments the laser module includes an array of semiconductor laser diode bars or a vertical-cavity surface-emitting laser array.

In various embodiments the reactor further includes a controller in communication with at least one sensor, the controller configured to control the position of the substrate based on information received from the at least one sensor.

In various embodiments the desired object is an array of silicon carbide fibers.

In another aspect, embodiments relate to a method for additive manufacturing. The method includes providing a reaction chamber having an intake for receiving a gaseous feedstock, an optical window, and a substrate; admitting the gaseous feedstock to the reaction chamber via the intake; and applying laser light to heat the substrate through the optical window and thereby drive a gas-to-solid deposition reaction in the vicinity of the heated substrate, converting the gaseous feedstock into at least one reaction product which forms at least part of a desired object supported by the substrate.

In various embodiments the method further includes moving the substrate through at least one degree of freedom to form the desired object.

In various embodiments the method further includes moving the laser light through at least one degree of freedom to form the desired object.

In various embodiments the method further includes adjusting one or more of the pressure of the reaction chamber, the temperature of the reactant, or the temperature of the substrate.

In various embodiments the reaction chamber further includes at least one sensor, and the method further includes controlling at least one of the power, the deflection, or the position of the laser light based on information received from the at least one sensor.

In various embodiments the at least one reaction product is a refractory material.

In various embodiments the desired object is an array of carbon fibers.

In various embodiments the reaction chamber further includes at least one sensor, and the method further includes controlling the position of the substrate based on information received from the at least one sensor.

In various embodiments the desired object is an array of silicon carbide fibers.

In yet another aspect, embodiments relate to a reactor for additive manufacturing. The reactor includes an intake for introducing gaseous reactants into a chamber and a source of laser radiation configured to convert the gaseous reactant into a solid product having a desired configuration.

### BRIEF DESCRIPTION OF DRAWINGS

Non-limiting and non-exhaustive embodiments of this disclosure are described with reference to the following figures, wherein like reference numerals refer to like parts throughout the various views unless otherwise specified:

FIG. 1 depicts an exemplary reactor concept for 3D printing;

FIG. 2 presents an exemplary semiconductor laser diode bar;

FIG. 3 shows an exemplary high-power laser module based on the diode bar of FIG. 2;

FIG. 4 depicts the casting of an array of spots onto a target substrate using a laser diode module and a single lens;

FIG. 5 presents an exemplary high-power laser module based on a VCSEL array;

FIG. 6 presents an exemplary laser reactor concept using laser diode bar modules;

FIG. 7 presents exemplary laser modules based on generic input beams;

FIG. 8 depicts a growth chamber having a motorized stage; and

FIG. 9 shows one example of an alignment plate concept.

### DETAILED DESCRIPTION

Various embodiments are described more fully below with reference to the accompanying drawings, which form a part hereof, and which show specific exemplary embodiments. However, the concepts of the present disclosure may be implemented in many different forms and should not be construed as limited to the embodiments set forth herein; rather, these embodiments are provided as part of a thorough and complete disclosure, to fully convey the scope of the concepts, techniques and implementations of the present disclosure to those skilled in the art. Embodiments may be practiced as methods, systems or devices. Accordingly, embodiments may take the form of a hardware implementation, an entirely software implementation or an implementation combining software and hardware aspects. The following detailed description is, therefore, not to be taken in a limiting sense.

Reference in the specification to “one embodiment” or to “an embodiment” means that a particular feature, structure, or characteristic described in connection with the embodiments is included in at least one example implementation or technique in accordance with the present disclosure. The appearances of the phrase “in one embodiment” in various places in the specification are not necessarily all referring to the same embodiment.

In addition, the language used in the specification has been principally selected for readability and instructional purposes and may not have been selected to delineate or circumscribe the disclosed subject matter. Accordingly, the present disclosure is intended to be illustrative, and not limiting, of the scope of the concepts discussed herein.

Recent technical advances have made it possible to precisely print three-dimensional structures (“3D printing”) in various materials, including plastics, composites, and metals. These approaches often involve converting a solid or liquid precursor material into the final product, e.g., by application of heat or light. Embodiments herein relate to methods and apparatuses for 3D printing a variety of materials directly from the gas phase using lasers.

Attractive features of this approach include high energetic efficiency, low cost, high throughput, ability to print refractory solids, and the possible coproduction of valuable gaseous byproducts (e.g., hydrogen, hydrocarbons, etc.). Embodiments may be used to 3D print, for example, solid carbon structures or arrays of carbon fibers from methane or other hydrocarbon precursors, yielding gaseous hydrogen as a saleable byproduct.

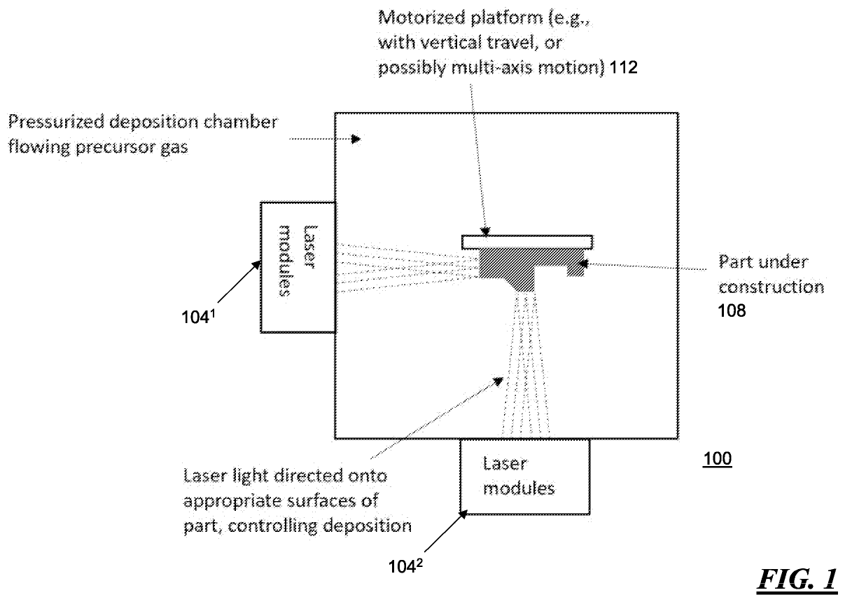

FIG. 1 depicts one novel reactor concept for 3D printing. A reaction chamber 100 is pressurized with appropriate precursor gases under appropriate flow and temperature. A motorized platform 112 inside the reaction chamber holds the part being 3D printed. One or more laser modules 104N (to be described in more detail below) cast an array of focused optical spots onto or near the part 108 inside the reaction chamber 100 via suitable optical access ports (e.g., optical windows, lenses, or other transmissive optical elements embedded in the wall of the reaction chamber 100 [not shown]; these may be constructed from, e.g., sapphire, diamond, fused silica, quartz, etc.). The laser modules 104 may modulate the power in each optical spot, and/or reposition the optical spots within the chamber in order to achieve a desired spatiotemporal heating profile that leads to suitable deposition of solid materials from the precursor gas phase. The part 108 is supported by a motorized stage 112 that may be repositioned to expose appropriate surfaces to the focused laser beams, enabling growth of the desired part 108.

It may be advantageous to flow coolant through channels (not shown) in the motorized stage 112 or other elements of the reactor 100 to extract heat. It may also be advantageous to supply additional heat (e.g. resistive, inductive, or radiative) to the part 108, the precursor gas, or other elements of the reactor 100. It may also be advantageous to suitably collect any generated particulate matter (e.g., pyrolysis products which did not deposit on the part; in the absence of such a collection scheme, such particulates could interfere with the optical path between laser module and part) using one or more schemes (e.g., electrostatic deflection of loose particles by applying suitable electrical potentials to suitably positioned electrodes and/or the part being fabricated, blowing loose particles away using appropriate gas flow patterns, intermittently sweeping away particles by mechanical means, etc.). One or more gas inlets (not shown) may be suitably positioned near optical surfaces in the reactor; a suitable gas mixture (e.g., precursor gas, inert gas, etc.) may be flowed into the chamber via these inlets in such a manner as to mitigate deposition of solids on optical surfaces.

To fabricate a desired 3D shape within this reactor, the movements of the motorized stage, the modulation of the laser modules, gas flow, coolant flow, and other reactor parameters (all of which may be digitally controlled) may be planned in advance, e.g., using suitable computer algorithms that account for pertinent physical effects (e.g., fluid dynamics, heat transport, etc.). These planned movements and adjustments may be further refined in real time using suitable algorithms operating on data collected from sensors (not shown) such as visible or infrared cameras (e.g., to image sections of the part being fabricated, to create temperature maps of the surface, etc.), lidar scanners or other depth sensors (e.g., to produce 3D maps of the part), auxiliary lasers (e.g., to monitor gas temperature, composition, and/or turbulence), thermometers, pressure sensors, gas flow meters, etc.

This reactor may be used in conjunction with various gaseous precursors to 3D print various solid materials. This method of using gaseous precursors may be advantageous for 3D printing parts of refractory materials such as solid carbon. In many cases, one or more gaseous coproducts are also generated via the pyrolysis reaction. For instance, hydrogen gas is generated in the pyrolysis of hydrocarbon precursor (e.g., methane, ethylene) when printing solid carbon. Such byproduct gases may be separated from the precursor gases emerging from the reactor (e.g., under conditions of continuous flow precursor gases flow into the chamber at a controlled rate, and a combination of excess precursor and byproduct gases emerge from an outlet port) by any suitable means (e.g., membranes, pressure-swing adsorption, cryogenic separation, etc.). The separated precursor gases may be recycled to the reaction chambers, while the byproduct gases may be sold or otherwise used. Hydrogen generated by this method may be “clean hydrogen” and may be sold into the market, or may be combusted to generate heat or electricity.

Heat carried by any gases or coolants emerging from the reactors may be fed into heat exchangers to heat gases (e.g., preheating of the input precursor may be desirable to reduce the needed input laser power, to improve growth quality, etc.), and/or may be used in conjunction with a suitable heat engine to generate electricity. Low temperature heat extracted from gases or coolants may find use in any other processing steps applied to the 3D printed part. Such steps will improve the net energetic efficiency of the growth and reduce production costs.

Other reactor variants similar to that depicted in FIG. 1 will be apparent to one of ordinary skill. For instance, the part may be entirely fixed in the reaction chamber, while only the focused beams are manipulated by the laser modules to control the spatiotemporal heating profile and thus the growth. Entire laser modules may alternatively be mounted on motorized platforms and moved around; the laser beams may be deflected by, e.g., fast-steering mirrors; the focused optical spots may be moved within the reactor by translating the emitter sources relative to a fixed lens; etc.

It may be useful to periodically or continuously remove deposits (e.g., deposits due to pyrolysis, contaminants, etc.) from optical surfaces. This may be accomplished by injection of suitable etchant gases into the reaction chamber, which may selectively etch deposits. Etchant gases may be injected during a designated cleaning period, or they may be injected along with the precursor during fiber growth. The etching process may be aided by laser heating (e.g., because the deposits are attached to optical surfaces within the beam path) or by a plasma discharge (e.g., an arc discharge, microwave plasma, etc.). Optical surfaces may also be cleaned mechanically, by applying a suitable etchant liquid to the surfaces or by other schemes. It may be useful to control the temperature of optical surfaces during operation to mitigate buildup of deposits, e.g., by leveraging thermophoresis.

### Laser Sources

There are several suitable options for the laser modules 104^{N}, which may be used in conjunction with suitable optics (e.g., lenses) to cast arrays of optical spots or other focused shapes onto the stage 112 or the part 108 being printed, thereby achieving a desired heating profile

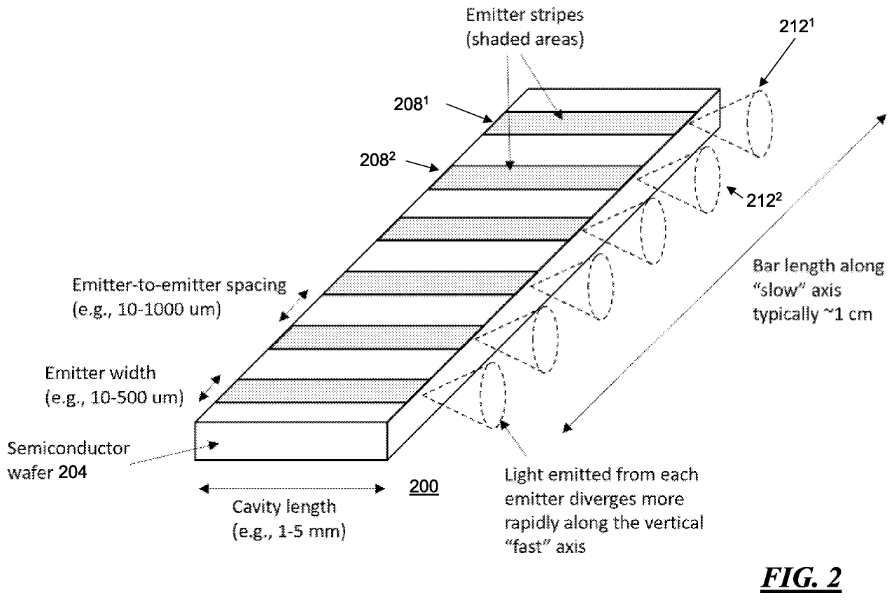

One laser module design is based on the semiconductor laser diode bar, illustrated in FIG. 2. A diode bar 200 is a piece of specialized semiconductor wafer 204 patterned to create a one-dimensional array of “emitters” 208^{N} (shaded for contrast), each of which constitutes a separate laser emitting a separate beamlet 212^{N} (depicted as cones), commonly in the near-infrared. The length of the bar 200 (also the cavity length) is often around one or several mm long, although other lengths are possible. The laser cavity of each emitter 208^{N} (typically a Fabry-Perot cavity) is often formed by the cleaved facets of the semiconductor wafer 204, which may be coated to tailor the reflection coefficient. The coatings are often chosen such that beamlets 212^{N} emerge from only one of the two facets of the semiconductor piece 204.

The width of each emitter 208^{N} in the periodic direction of the array 200 is usually considerably larger than a wavelength, e.g., 10-500 microns, whereas the height of each emitter (i.e., the vertical direction in FIG. 2) is typically small enough to confine a single optical mode in that dimension. The net result is that the beam 212^{N} emerging from each emitter 208^{N} often has considerable divergence (e.g., 40 degrees) and near-diffraction-limited beam quality along the vertical direction (i.e., the “fast” axis), whereas the divergence is much smaller (e.g., well below 10 degrees) along the periodic direction (i.e., “slow” axis) but with lower beam quality.

The spacing between adjacent emitters 208^{N} (“emitter-to-emitter spacing” in FIG. 2) is often tens to hundreds of microns, with a wide range of possible fill factors (i.e., the fraction of the full width of the diode bar 200 that is filled with emitters 208^{N}). Each diode bar 200 is often around 1 cm wide in the periodic direction, although other widths are possible, and there may be a wide range of individual emitters 208^{N} within this width (e.g., 10-200 emitters). The width along the slow axis of an emitter 208^{N} may also vary greatly between different diode bars.

The electrical-to-optical conversion efficiency of diode bars is often very high (e.g., 50-80% in modern devices), which is an important feature for laser printing from a gaseous feedstock, and the capital cost per watt is low compared to most other laser technologies. The maximum optical power achievable per emitter may vary between, e.g., 0.01 W and 10 W depending on design details, while the maximum total continuous-wave optical power per cm may be in the hundreds of watts.

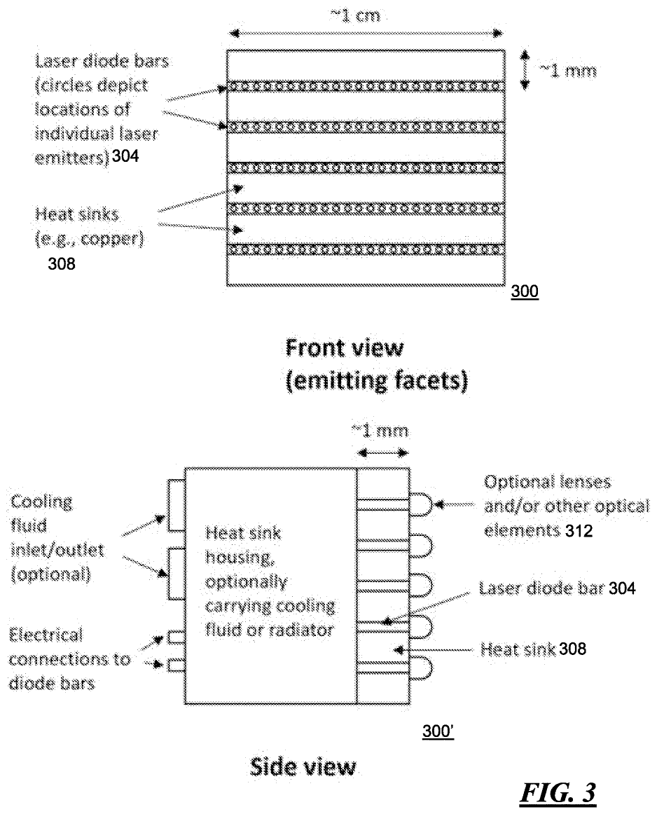

Using simple optics (e.g., i.e., low cost and with few optical surfaces, minimizing optical loss), it is possible to “reimage” the emitting facet of the diode bar to cast an array of optical spots onto or near the part being printed. FIG. 3 depicts one example of a laser diode module 300 which may be used to implement this concept, showing a view from the “front” (which contains the emitting facets of the individual semiconductor laser diode bars 304) and a view from the “side.” In the side view, optional optical elements (e.g., lenses) 308 are shown affixed to the module 300. These optical elements 308 may be aligned to individual emitters or rows of emitters.

This module stacks multiple diode bars 304 to form a two-dimensional array of emitters. The diode bars 304 are mounted in contact with appropriately sized heat sinks 308 (e.g., copper or other material with suitably high thermal conductivity) that may be connected to suitable structures for removing heat from the full assembly (e.g., microchannels carrying coolant, radiators for air-cooling, etc.). The electrical pads of the diode bars 304 may be contacted using typical means (e.g., wirebonds, conductive paste, solder, direct metal-to-metal contact, etc.). It may be advantageous to independently control the drive current, and thus the emitted power, of different emitters in the array; to this end, separate electrical connections may be made to individual laser diodes (or groups of laser diodes) within the array.

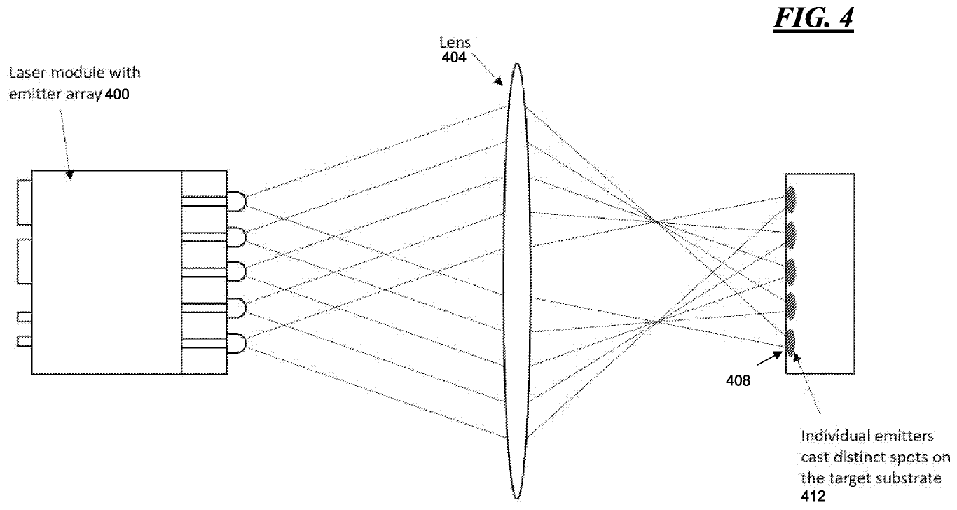

FIG. 4 demonstrates how the aforementioned laser diode modules may be used to cast an array of spots onto or near the printed part. In this depiction, a single laser diode module 400 having a two-dimensional array of emitters (as shown in FIG. 3) casts light collected by a single lens 404 to cast an array of spots 408 onto a target substrate 412. It may be advantageous to attach small optics (e.g., microlenses) to one or more of the emitters, e.g., to adjust the beam divergence of the emitters in the fast axis, to compensate for distortions in the off-axis spots, etc. In this side view, only one laser module 400 is shown, but an arbitrary number may be tiled along multiple axes in this fashion.

The emitting facets of each laser module 400 are reimaged by one or more lenses 404 to cast an array of optical spots 408 into the reactor filled with an appropriate precursor gas. Solid material is deposited near the optical spots 408 at a rate dependent on the focused optical power and other conditions. To grow a desired three-dimensional object, the array of optical spots 408 may be moved relative to the part (e.g., by moving the part on a motorized stage, by moving the emitters relative to the focusing lens, by moving the entire laser module relative to the chamber, by deflecting the light using a motorized mirror, etc.) and/or the optical power of individual focused spots within the array may be temporally modulated (e.g., by modulating the drive current to individual laser diodes in the array) to create a suitable spatiotemporal heating profile.

The specific parameters of each individual diode bar in the array may be chosen as appropriate for the growth (e.g., geometric parameters like emitter widths and lengths may be increased to favor higher power per emitter, electrical parameters like drive currents may be used to fine tune optical power, etc.), and in keeping with requirements on thermal dissipation within the overall laser module assembly 400. As an example, to cast a dense array of approximately 10-micron-diameter spots into the growth plane, the laser module might contain diode bars with emitter width 10 μm and emitter-to-emitter spacing of 40 μm. A short cavity length (e.g., ~1 mm) may be suitable. Diode bars might be stacked on thin copper heat sinks such that the separation between emitter chips is ~1 mm. The resulting array of emitters could be reimaged into a deposition chamber filled with appropriate precursor gas using a simple lens with unity magnification.

It may be advantageous to shape individual beamlets, or rows of beamlets, using small optical elements (such as cylindrical or other lenses), e.g., to compensate for the fast-axis divergence, to tune the shape of the optical spots focused into the growth chamber, to combat optical aberrations and improve uniformity of the array of optical spots, etc. The use of micro-lenses to reduce the fast-axis divergence may be particularly helpful in reducing the required clear aperture of the lens that reimages the emitter array, and also as a means to produce round rather than elliptical optical focused spots if this is deemed desirable. Note that it may or may not be advantageous to have the focused optical spots from adjacent emitters spatially overlap with each other, depending on details such as gas convection and diffusion, gas temperature profiles, etc. Both overlapping and non-overlapping arrangements in the focal plane may be achieved by appropriate choice of lenses.

Diode bars suitable for the current application may stand in contrast to those configured for typical commercial applications (e.g., laser cutting and welding, optical pumping of other lasers, etc.). For typical commercial applications, maximizing power and brightness per emitter is often desired. This may be achieved by increasing the area per emitter (i.e., by making wider and longer emitters). However, making longer emitters may increase optical loss and thus reduce the electro-optical conversion efficiency of the lasers, while making wider emitters may reduce the beam quality along the slow axis.

For the current application, the desired power per emitter may be low enough (e.g., well below 1 W in some cases) to allow the use of shorter cavity lengths with commensurate improvements in laser efficiency, as well as smaller emitter widths with commensurate improvements in beam quality. Since the current application does not necessarily require coupling the light from the diode bars into an optical fiber, as is often the case in other contexts, and may use relatively few optical elements, the end-to-end efficiency (electrons in wall to photons focused on target) may be very high (e.g., well in excess of 50%), while the capital cost per watt for the entire laser system may be very low (e.g., because assembly requirements are minimal and the cost of the bare semiconductor chips is low). The spectral requirements are also not demanding, which permits the selection of the wavelengths that optimize desired system parameters (e.g., wall-plug efficiency, cost, etc.); for instance, to deposit solid carbon from hydrocarbon precursor gas, most wavelengths in the near infrared will absorb well on to a previously deposited carbon surface, as well as on various substrates that may be used to begin the growth (e.g., ceramics).

Another laser module design, which also creates a 2D array of emitters that may be used for 3D printing via the scheme of FIG. 4, is based on vertical-cavity surface-emitting lasers (VCSELs). VCSELs are individual laser emitters formed using a patterned semiconductor wafer, with the emitting apertures on one of the wafer surfaces rather than the cleaved wafer facets. Dense arrays of VCSELs may be produced, with individual VCSELs emitting an optical power ranging from, e.g., 1 mW to several hundred mW, with laser wavelengths commonly in the near-infrared. The total optical power emitted per unit surface area of a VCSEL array can be quite high (e.g., ~1 kW/cm²), and the electrical-to-optical conversion efficiency may also be high (e.g., above 50%). The capital cost per watt of VCSEL arrays may be quite low.

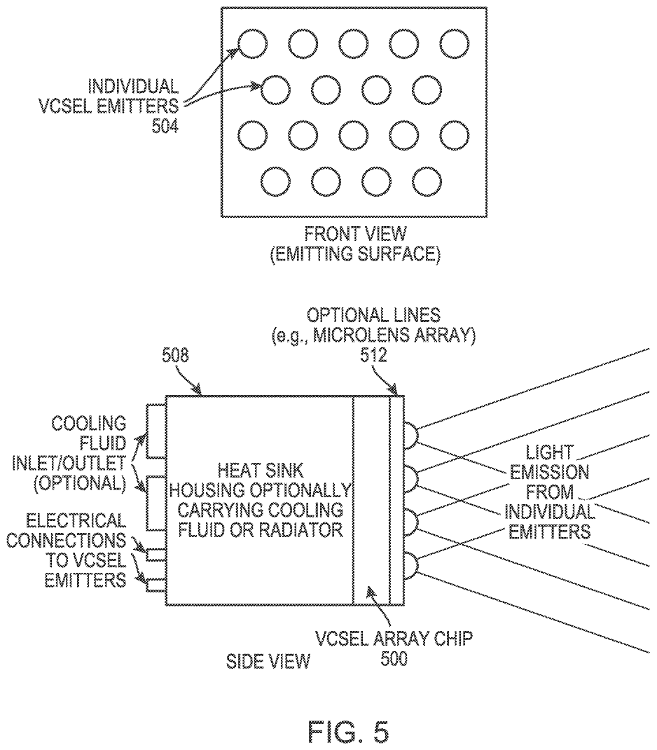

An exemplary high-power laser module based on a VCSEL array is shown in FIG. 5. The front view depicts the emitting surface of a VCSEL array chip 500, which is a piece of semiconductor wafer containing a two-dimensional array of individual VCSEL emitters 504. As shown in the side view, the VCSEL array 500 is mounted to a suitable heat sink 508 with suitable electrical connections forming a laser module suitable for use in the current application. The emitting surface of the VCSEL array is faced away from the heat sink 508. Lenses 512 (e.g., a microlens array) may be used to adjust the bean divergence or other beam properties.

As with the laser diode bars, it may be advantageous to supply separate electrical contacts to individual VCSEL emitters. Alternatively (e.g., if contacts to individual VCSEL emitters are challenging to fabricate owing to geometric or other constraints), it may be advantageous to implement a “matrix-addressed” scheme, in which separate contacts to each row and column of the device are fabricated. In the matrix-addressed scheme, it may not be possible to supply power to a desired, arbitrarily chosen set of emitters. But an arbitrary set of emitters within a particular row, for instance, may be simultaneously powered by applying suitable voltages to the row and column(s) in question. Since VCSEL emitters may be modulated on very short timescales (e.g., sub-nanosecond timescales in some devices), whereas the thermal time constants associated with the 3D printing reaction may be much longer, it may be possible in a matrix-addressed scheme to use temporal multiplexing to create an appropriate heating profile (e.g., by powering appropriate columns while rapidly cycling through rows).

It should be noted that other laser module designs are possible. Any suitable intense light source may be used for 3D printing from the gas phase, as long as the apparatus provides a means by which the light source can be moved around on the object being printed. For instance, a suitably intense beam of light may be steered around on a target by a fast-steering mirror, or the part may be moved within and around a fixed light beam using a motorized stage. The methods and apparatus described herein (which enables efficient, spatiotemporally reconfigurable laser heating for deposition) may additionally be useful for 3D printing from liquid or solid precursors (e.g., solid carbon may be deposited from liquid hydrocarbons using our laser apparatus, solid powders may be sintered using our laser apparatus, etc.).

Various other extensions and modifications of the concepts described above may be advantageous. As one example, this laser-induced, gas-phase 3D printing method may be combined with another 3D printing method (e.g., fused deposition modeling) to produce a composite material (e.g., solid carbon or boron deposited from the gas phase via laser as described herein, co-deposited with a thermoplastic or other polymer deposited by fused deposition modeling). As another example, a material (e.g., polymer, aluminum, etc.) may be first processed via any suitable means (e.g., 3D printing, CNC milling) and subsequently inserted into the laser-based 3D printer for additional material deposition (e.g., for additional reinforcement, to construct a useful composite, etc.) and/or removal (e.g., by laser ablation).

As another extension of the laser-based 3D printing methods described herein, the precursor gas may be switched or continuously modulated in order to tune the material composition and properties of the deposited solid.

As another extension of the laser-based 3D printing methods described herein, process steps such as shutting off the precursor gas and evacuating the chamber or changing the input gas composition to a specific species (capable of reacting with the deposited solid material) may cause the focused intense laser radiation on the workpiece to effect a subtraction, not addition, of solid material by driving removal processes such as ablation or oxidation. In this way, a deliberate laser trimming the shape of the workpiece can be accomplished in situ after or in between deposition sequences.

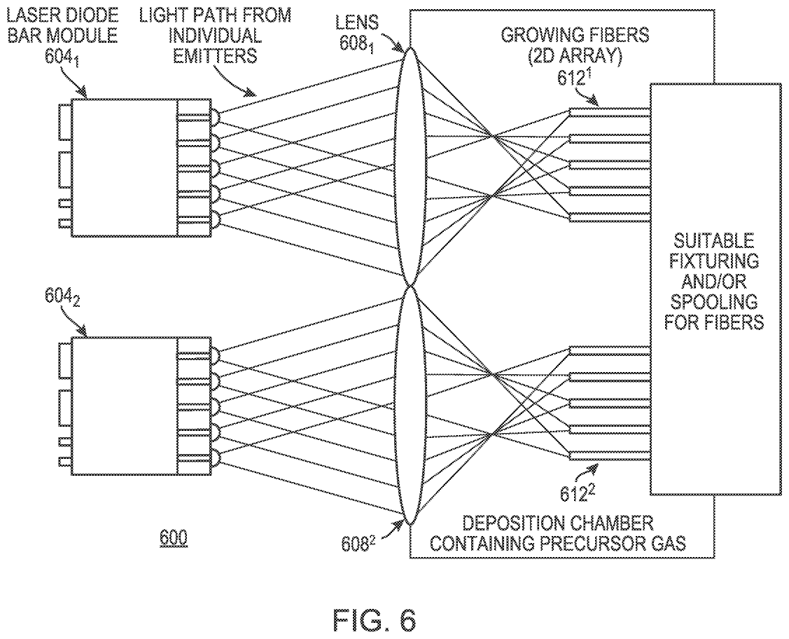

FIG. 6 presents one example of a laser reactor 600 using the aforementioned laser diode bar modules 604^{N} to grow arrays of fibers. In this side view, only two laser modules 604^{N} are shown, but an arbitrary number may be tiled along multiple axes in this fashion. Each module 604^{N} contains a two-dimensional array of emitters (as shown in FIGS. 3 and 5); the light from the emitting facets of each module 604^{N} is collected by a lens 608^{N} and reimaged to cast an array of optical spots into a growth chamber filled with appropriate precursor gas; a two-dimensional array of fibers 612^{N} grows as gas pyrolyzes within the hot spots created by the focused laser beams. The focal plane of the optical spots in this example is fixed; the array of fibers 612^{N} should be steadily pulled away (to the right) as the fibers grow to keep the position of the growing fiber tips approximately constant in space.

The specific parameters of the diode bar may be chosen as appropriate for the growth (e.g., geometric parameters like emitter widths and lengths may be increased to favor higher power per emitter, electrical parameters like drive currents may be used to fine tune optical power, etc.), and in keeping with requirements on thermal dissipation within the laser module assembly. As an example, to grow a dense array of approximately 10-micron-diameter fibers, the laser module might contain diode bars with emitter width 10 μm and emitter-to-emitter spacing of 40 μm. A short cavity length (e.g., ~1 mm) may be suitable. Diode bars might be stacked on thin copper heat sinks such that the separation between emitter chips is ~1 mm. The resulting array of emitters could be reimaged into a deposition chamber filled with appropriate precursor gas using a simple lens with unity magnification.

It may be advantageous to shape individual beamlets, or rows of beamlets, using small optical elements (such as cylindrical or other lenses), e.g., to compensate for the fast-axis divergence, to tune the shape of the optical spots focused into the growth chamber, to combat optical aberrations and improve uniformity of the array of optical spots, etc. The use of micro-lenses to reduce the fast-axis divergence may be particularly helpful in reducing the required clear aperture of the lens that reimages the emitter array, and also as a means to produce round rather than elliptical optical focused spots (although fibers grown with elliptical spots may be of interest in some circumstances, e.g., to produce fibers with mechanical anisotropy).

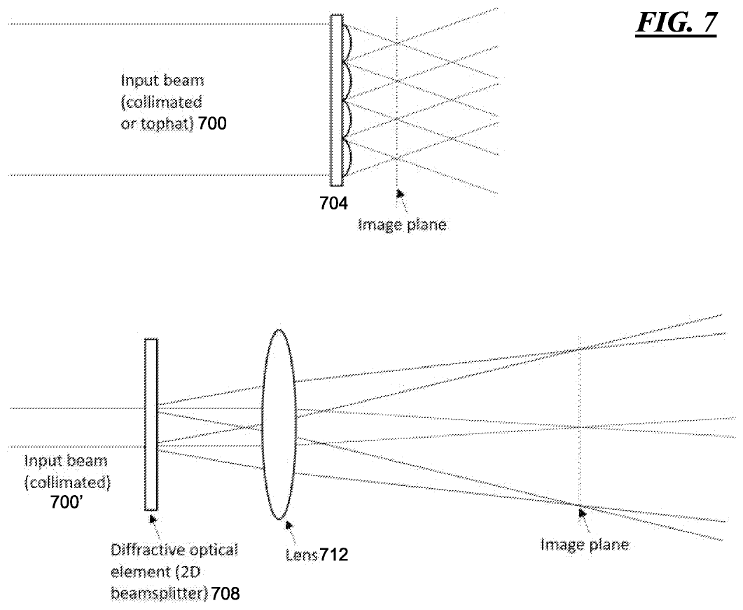

Two other preferred laser module designs, which may be used in conjunction with an arbitrary optical source producing a beam of light (e.g., a fiber laser), are depicted in FIG. 7. In one design, an input optical beam (e.g., collimated, or shaped by a top-hat optic) strikes a microlens array, which casts an array of focused spots. This array may be formed in an intermediate plane which is subsequently reimaged into the fiber growth chamber using a lens, as in the scheme of FIG. 6. Alternatively the microlens array may focus its light directly into the growth chamber.

The bottom implementation of FIG. 7 shows a collimated input beam 700′ traversing a diffractive optical “beamsplitter” element 708 which splits the incident input beam into multiple output beams with different propagation vectors. These individual beams may be focused (e.g., using a single lens 712) into a one or two-dimensional array of spots. The power distributed into each beam may be appropriately chosen (e.g., such that all beams may carry approximate equal optical powers).

### Fiber Growth Chambers

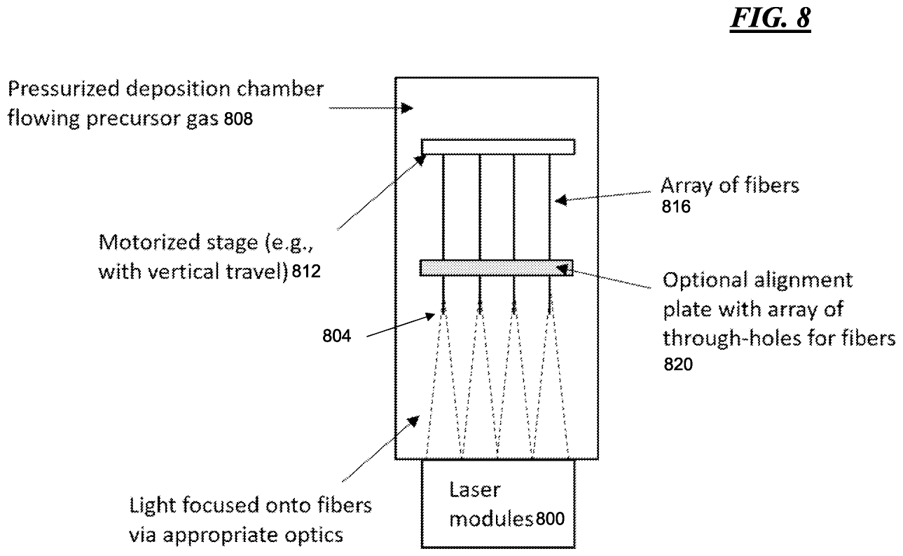

One approach for growing fibers of a limited length is shown in FIG. 8. Laser modules 800 (e.g., any of the laser modules described above) cast a two-dimensional array of spots 804 into a growth chamber 808, which is appropriately pressurized (e.g., to optimize growth conditions) and flowing appropriate precursor gas. The precursor initially pyrolyzes onto a suitable substrate material which is mounted to a motorized platform 812. This platform 812 is withdrawn at a rate commensurate with fiber growth. The length of fiber grown this way is limited by the platform travel. As the array of spots is two-dimensional, the array of fibers 816 should be understood to extend out of the plane of the drawing as well as within the plane.

Depending on the properties of the grown fibers (e.g., stiffness, length), it may be advantageous to orient the chamber such that the motorized platform pulls upward against gravity, which minimizes the opportunity for the fibers to flex during growth and come out of alignment with their associated optical spots. It may further be advantageous to flow precursor gas against gravity, or otherwise at a sufficiently high flow rate, to avoid deposition of solids on the optical windows, and to keep any loose solids out of the optical beams to the extent possible. Minimization of relative vibration between the laser modules and the fiber ends may be very helpful; this may be accomplished by using smooth, low-vibration motorized platforms, minimizing vibrations from the surrounding environment, minimizing turbulence in the flow of precursor gas, etc. Vibrations may alternatively be minimized by flipping the chamber upside down such that the bases of the growing fibers may be immersed in a viscous fluid, confined to the chamber by gravity. In all cases, it may be advantageous to use the flowing precursor gas to carry away heat from the reactor; this may require suitably high flow rates and/or suitable cooling apparatus installed the chamber (e.g., metal fins connected to blocks with circulating coolant).

To further aid in stabilizing the positions of the growing fiber ends relative to the optical foci, an alignment plate 820 patterned with an array of through-holes may optionally be used, e.g., in the manner depicted in FIG. 8, to hold the ends of the fibers within the appropriate laser beams, mitigating effects of vibration, fiber deflection from gas flow, etc. The alignment plate 820 may be manufactured using a material with suitable resistance to temperature, thermal expansion coefficient, thermal conductivity, etc. ; preferred materials may include sapphire, aluminum nitride, silica, silicon, or other suitable materials. The alignment plate 820 may be fabricated using, e.g., standard lithographic techniques, laser cutting, waterjet cutting, etc.

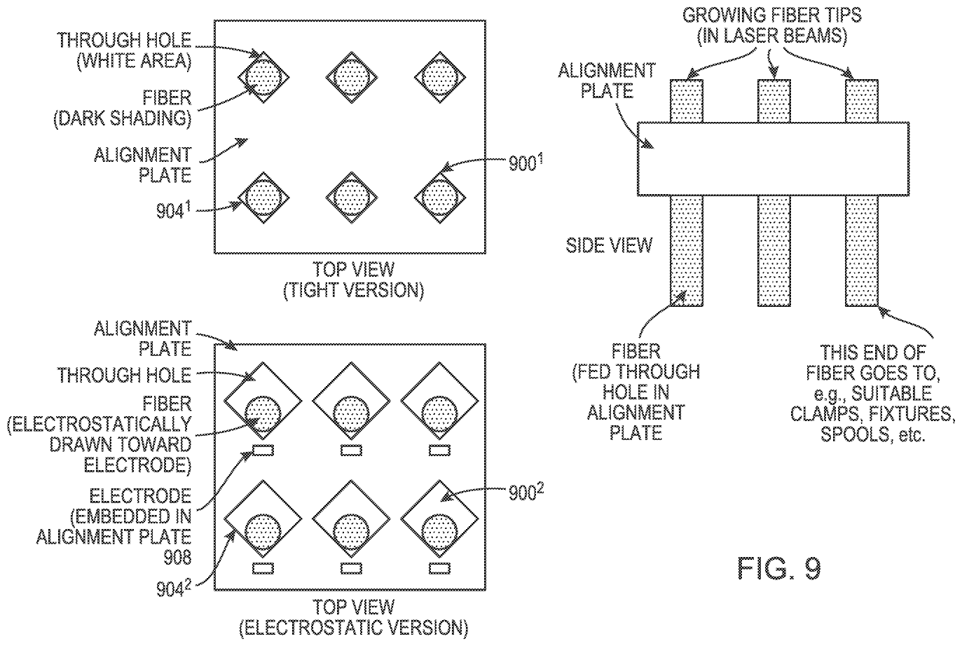

FIG. 9 presents one embodiment for an alignment plate. The alignment plate contains an array of holes 900^{N} through which the growing array of fibers 904^{N} may be fed. These holes may be tightly matched to the diameter of the grown fibers, as shown in the upper left of the figure. Alternatively, looser through-holes may be used, which may have advantages for handling growth nonuniformities, mitigating clogging problems, etc. In the case of looser through-holes, it may be useful to position the fibers deterministically within the through holes using, e.g., electrostatic forces. The alignment plate may optionally contain embedded electrodes 908, which may be used to suitably deflect fibers 904² within larger holes 900² using electrostatic forces, as shown in the lower left of the figure. Suitable electrical connections may be made to these electrodes (not shown).

For instance, also as depicted in FIG. 9, electrodes 908 may be embedded in the alignment plate (e.g., using lithographic techniques) near the loose holes 900². If the fiber 904² is adequately conductive, an electrical contact may be made to the fibers 904^{N} (e.g., using a conductive roller [not shown]), and a voltage difference may be applied between the electrodes 908 on the alignment plate and the fibers 904^{N}, this may serve to pull the fibers 904^{N} into a well-defined position in the through-holes 900^{N}.

Alternatively, electrostatic forces may be used to center the fibers within the through-holes. To accomplish this, suitable electrodes may be patterned around the holes in the alignment plate or on another suitable structure, and an electric charge may be deposited on these electrodes; alternatively, the alignment plate may be made partly or wholly of insulating material into which static charges may be embedded. Electric charges of the same sign as those deposited onto the alignment plate may be simultaneously maintained near the growing fiber ends (e.g., by applying a voltage between fiber and a suitable metallic structure near the tips), leading to repulsion between the fiber and the edges of the through-holes. Electrodes used for any of the above schemes may be embedded in suitable insulators to mitigate concerns about electrical short circuits, dielectric breakdown owing to high voltages, etc.

If tight alignment tolerances are required, the alignment plates may be aligned to the laser spots using, e.g., micro- or nano-positioners (e.g., stepper motors, piezoelectrics), and may leverage active feedback schemes to maintain alignment (e.g., an optical camera may be used to observe the location of the spots on the alignment plate, and these images may be used to actively correct the position of either the alignment plates or the laser spots. It may also be advantageous to fabricate the alignment plate entirely or partially in situ (i.e., in the reaction chamber). For instance, the laser spots may be cast onto a suitable photosensitive or heat-sensitive material (e.g., photoresist, thermoplastics, etc.) mounted in the position of the alignment plate. The precise positions of the spots are thus imprinted into the material, which may then be suitably processed (e.g., by chemical etching, thermal treatment, etc.), in situ or ex situ, to yield a suitable alignment plate.

The laser growth chambers presented here may be readily parallelized to achieve the needed growth throughput in a commercial facility within a reasonable footprint. For instance, consider building a world-scale carbon fiber growth facility producing 5,000 tons of solid carbon per year. If the growth rate is 1 mm/s, the fiber diameter is 10 microns, and the density is assumed to be 2 g/cm³, approximately 1 billion fibers must be constantly grown in parallel. To accomplish this within a modest footprint of 1000 m² using the vertical growth concepts disclosed herein, roughly one million fibers would need to be grown per square meter of floorspace. Such a spot density is achievable using the above-described laser module concepts.

For example, consider a laser diode bar module with 10 micron emitter width, 40 micron emitter-to-emitter spacing, and 1 mm separation between rows of emitters in the stack of diode bars. This corresponds to an emitter density of 20 million emitters per square meter, or twenty times the desired density of optical spots, leaving ample margin for separation between laser modules (e.g., to accommodate the diverging beams from the emitters within the clear aperture of the imaging lenses). Furthermore, the power density requirements are reasonable. If the power required per optical spot is on the order of 0.1 W, the needed optical power density averaged over the facility is then only ~10 W/cm², which is orders of magnitude below the power density limits (which may be set by, e.g., thermal constraints) of the laser modules presented here.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Embodiments of the present disclosure, for example, are described above with reference to block diagrams and/or operational illustrations of methods, systems, and computer program products according to embodiments of the present disclosure. The functions/acts noted in the blocks may occur out of the order as shown in any flowchart. For example, two blocks shown in succession may in fact be executed substantially concurrent or the blocks may sometimes be executed in the reverse order, depending upon the functionality/acts involved. Additionally, or alternatively, not all of the blocks shown in any flowchart need to be performed and/or executed. For example, if a given flowchart has five blocks containing functions/acts, it may be the case that only three of the five blocks are performed and/or executed. In this example, any of the three of the five blocks may be performed and/or executed.

A statement that a value exceeds (or is more than) a first threshold value is equivalent to a statement that the value meets or exceeds a second threshold value that is slightly greater than the first threshold value, e.g., the second threshold value being one value higher than the first threshold value in the resolution of a relevant system. A statement that a value is less than (or is within) a first threshold value is equivalent to a statement that the value is less than or equal to a second threshold value that is slightly lower than the first threshold value, e.g., the second threshold value being one value lower than the first threshold value in the resolution of the relevant system.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations will provide those skilled in the art with an enabling description for implementing described techniques. Various changes may be made in the function and arrangement of elements without departing from the spirit or scope of the disclosure.

Having described several example configurations, various modifications, alternative constructions, and equivalents may be used without departing from the spirit of the disclosure. For example, the above elements may be components of a larger system, wherein other rules may take precedence over or otherwise modify the application of various implementations or techniques of the present disclosure. Also, a number of steps may be undertaken before, during, or after the above elements are considered.

What is claimed is:

1. A laser reactor for additive manufacturing, the reactor comprising:
a reaction chamber having:
an intake for receiving a gaseous feedstock;
an optical window; and
a substrate; and
a laser module, wherein the laser module is configured to emit laser light to heat the substrate through the window and thereby drive a gas-to-solid deposition reaction in the vicinity of the heated substrate converting the gaseous feedstock into at least one reaction product which forms at least part of a desired solid object supported by the substrate.

2. The reactor of claim 1 wherein the substrate has at least one degree of freedom.

3. The reactor of claim 1 wherein the at least one reaction product is a refractory material.

4. The reactor of claim 1 wherein the laser module is mobile and has at least one degree of freedom.

5. The reactor of claim 1 wherein the laser module comprises a plurality of laser emitters, and the reactor further comprises an optical mechanism configured to cause the output of each of the laser emitters to strike different areas of the substrate.

6. The reactor of claim 1 further comprising a first optical element to split the output of the laser module into multiple beams and a second optical element configured to cause each beam to strike a different area of the substrate.

7. The reactor of claim 1 further comprising a plurality of optical windows and a plurality of laser modules, wherein each laser module of the plurality of laser modules is configured to emit laser light into the chamber through an optical window of the plurality of optical windows and the laser light of the plurality of laser modules converges on an area of the substrate.

8. The reactor of claim 1 further comprising a mechanism for adjusting one or more of the pressure of the reactor, the temperature of the substrate, or the temperature of the reactants.

9. The reactor of claim 1 further comprising an optical element for controlling the target of the emitted laser light in the reaction chamber.

10. The reactor of claim 1 further comprising a controller in communication with at least one sensor, the controller configured to control at least one of the power, the deflection, or the position of the laser module based on information received from the at least one sensor.

11. The reactor of claim 1 wherein the desired object is an array of carbon fibers.

12. The reactor of claim 1 wherein the laser module includes an array of semiconductor laser diode bars or a vertical-cavity surface-emitting laser array.

13. The reactor of claim 1 further comprising a controller in communication with at least one sensor, the controller configured to control the position of the substrate based on information received from the at least one sensor.

14. The reactor of claim 1 wherein the desired object is an array of silicon carbide fibers.

15. A method for additive manufacturing, the method comprising:
providing a reaction chamber having an intake for receiving a gaseous feedstock, an optical window, and a substrate;
admitting the gaseous feedstock to the reaction chamber via the intake; and
applying laser light to heat the substrate through the optical window and thereby drive a gas-to-solid deposition reaction in the vicinity of the heated substrate converting the gaseous feedstock into at least one reaction product which forms at least part of a desired object supported by the substrate.

16. The method of claim 15 further comprising moving the substrate through at least one degree of freedom to form the desired object.

17. The method of claim 15 further comprising moving the laser light through at least one degree of freedom to form the desired object.

18. The method of claim 15 further comprising adjusting one or more of the pressure of the reaction chamber, the temperature of the reactant, or the temperature of the substrate.

19. The method of claim 15 wherein the reaction chamber further comprises at least one sensor, and the method further comprises controlling at least one of the power, the deflection, or the position of the laser light based on information received from the at least one sensor.

20. The method of claim 15 wherein the at least one reaction product is a refractory material.

21. The method of claim 15 wherein the desired object is an array of carbon fibers.

22. The method of claim 15 wherein the reaction chamber further comprises at least one sensor, and the method further comprises controlling the position of the substrate based on information received from the at least one sensor.

23. The method of claim 15 wherein the desired object is an array of silicon carbide fibers.
